(19) United States
(12) Patent Application Publication
(10) Pub. No.: US 2024/0203728 A1
(43) Pub. Date: Jun. 20, 2024

(54) SEMICONDUCTOR DEVICE AND METHOD OF MANUFACTURING THE SAME

(71) Applicant: Kioxia Corporation, Tokyo (JP)

(72) Inventors: Junya FUJITA, Nagoya (JP); Satoshi YOSHIDA, Yokkaichi (JP)

(73) Assignee: Kioxia Corporation, Tokyo (JP)

(21) Appl. No.: 18/536,768

(22) Filed: Dec. 12, 2023

(30) Foreign Application Priority Data
Dec. 16, 2022 (JP) 2022-201592

(51) Int. Cl. H01L 21/02

(52) U.S. Cl. CPC H01L 21/02211; H01L 21/0214; H01L 21/02164; H01L 21/02216; H01L 21/0228

(57) ABSTRACT

In one embodiment, a method of manufacturing a semiconductor device includes supplying first silane-based gas to a surface of a first film, the first silane-based gas being aminosilane-based gas. The method further includes supplying second silane-based gas to the surface of the first film, the second silane-based gas having a thermal decomposition temperature lower than a thermal decomposition temperature of the first silane-based gas. The method further includes supplying an oxidant to the surface of the first film to form a second film on the surface of the first film, the second film including silicon and oxygen.

### CROSS-REFERENCE TO RELATED APPLICATIONS

This application is based upon and claims the benefit of priority from the prior Japanese Patent Application No. 2022-201592, filed on Dec. 16, 2022, the entire contents of which are incorporated herein by reference.

### FIELD

Embodiments described herein relate to a semiconductor device and a method of manufacturing the same.

### BACKGROUND

To form a high-quality SiO₂ film (silicon oxide film), it is needed to form the SiO₂ film at high temperature. However, it is difficult to form the SiO₂ film at high temperature in some cases.

### BRIEF DESCRIPTION OF THE DRAWINGS

FIG. 1 is a perspective view illustrating the structure of a semiconductor device of a first embodiment;

FIGS. 2 to 7 are cross-sectional views illustrating a method of manufacturing the semiconductor device of the first embodiment;

FIGS. 8A to 9B are cross-sectional views illustrating details of the method of manufacturing the semiconductor device of the first embodiment;

FIGS. 10A and 10B are cross-sectional views illustrating the method of manufacturing the semiconductor device of the first embodiment;

FIG. 11 is a schematic diagram illustrating a method of manufacturing a semiconductor device of a comparative example of the first embodiment; and

FIG. 12 is a schematic diagram illustrating the method of manufacturing the semiconductor device of the first embodiment.

### DETAILED DESCRIPTION

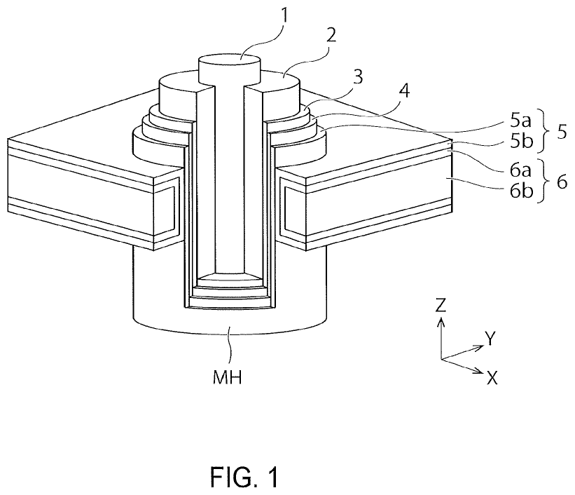

Embodiments will now be explained with reference to the accompanying drawings. Identical components in FIGS. 1 to 12 are denoted by the same reference sign, and duplicate description thereof is omitted.

In one embodiment, a method of manufacturing a semiconductor device includes supplying first silane-based gas to a surface of a first film, the first silane-based gas being aminosilane-based gas. The method further includes supplying second silane-based gas to the surface of the first film, the second silane-based gas having a thermal decomposition temperature lower than a thermal decomposition temperature of the first silane-based gas. The method further includes supplying an oxidant to the surface of the first film to form a second film on the surface of the first film, the second film including silicon and oxygen.

### First Embodiment

FIG. 1 is a perspective view illustrating the structure of a semiconductor device of a first embodiment. The semiconductor device of the present embodiment includes, for example, a three-dimensional semiconductor memory.

The semiconductor device of the present embodiment includes a core insulator 1, a channel semiconductor layer 2, a tunnel insulator 3, a charge storing layer 4, a block insulator 5, and an electrode layer 6. The block insulator 5 includes an insulator 5a and an insulator 5b. The electrode layer 6 includes a barrier metal layer 6a and an electrode material layer 6b.

In FIG. 1, a plurality of electrode layers and a plurality of insulators are alternately stacked on a substrate, and a memory hole MH is provided in these electrode layers and insulators. FIG. 1 illustrates the electrode layer 6 as one of the electrode layers. Each electrode layer functions as, for example, a word line or selection line of the three-dimensional semiconductor memory. FIG. 1 illustrates an X direction and a Y direction parallel to the surface of the substrate and orthogonal to each other, and a Z direction orthogonal to the surface of the substrate. In the present specification, the positive Z direction is treated as an upward direction, and the negative Z direction is treated as a downward direction. The negative Z direction may be or may not be aligned with the direction of gravity. The Z direction is an example of a first direction, and the Y direction is an example of a second direction.

The core insulator 1, the channel semiconductor layer 2, the tunnel insulator 3, the charge storing layer 4, and the insulator 5a are formed in the memory hole MH and constitute a memory cell of the three-dimensional semiconductor memory. The insulator 5a is formed on side faces of the electrode layers and the insulators in the memory hole MH, and the charge storing layer 4 is formed on a side face of the insulator 5a. The charge storing layer 4 can store signal charges of the three-dimensional semiconductor memory. The tunnel insulator 3 is formed on a side face of the charge storing layer 4, and the channel semiconductor layer 2 is formed on a side face of the tunnel insulator 3. The channel semiconductor layer 2 functions as a channel of the three-dimensional semiconductor memory. The core insulator 1 is formed on a side face of the channel semiconductor layer 2.

The insulator 5a is, for example, a SiO₂ film (silicon oxide film). The charge storing layer 4 is, for example, a SiN film (silicon nitride film). The tunnel insulator 3 is, for example, a SiO₂ film. The channel semiconductor layer 2 is, for example, a polysilicon layer. The core insulator 1 is, for example, a SiO₂ film.

The memory hole MH has a column shape extending in the Z direction and has a circular shape in a plan view. Accordingly, the core insulator 1, the channel semiconductor layer 2, the tunnel insulator 3, the charge storing layer 4, and the insulator 5a in the memory hole MH form a columnar portion having a column shape extending in the Z direction. The columnar portion is an example of a first columnar portion.

The insulator 5b, the barrier metal layer 6a, and the electrode material layer 6b are formed between two insulators of the above-described plurality of insulators and sequentially formed on a lower face of the upper insulator, an upper face of the lower insulator, and the side face of the insulator 5a. The insulator 5b is, for example, an Al₂O₃ film (aluminum oxide film). The barrier metal layer 6a is, for example, a TiN film (titanium nitride film). The electrode material layer 6b is, for example, a W (tungsten) layer.

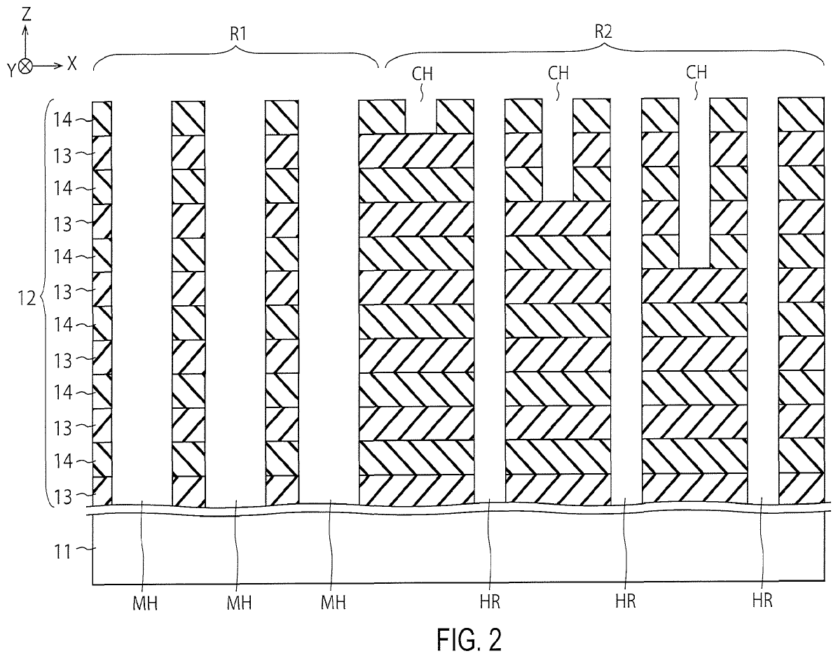

FIGS. 2 to 7 are cross-sectional views illustrating a method of manufacturing the semiconductor device of the first embodiment.

First, a substrate 11 is prepared, and a stacked film 12 is formed on the substrate 11 (FIG. 2). The stacked film 12 includes a plurality of sacrificial layers 13 and a plurality of insulators 14 alternately stacked in the Z direction. The stacked film 12 is formed by alternately stacking the sacrificial layers 13 and the insulators 14 on the substrate 11. The stacked film 12 may be directly formed on the substrate 11 or may be formed on the substrate 11 with another layer interposed therebetween. The substrate 11 is, for example, a semiconductor substrate such as a Si (silicon) substrate. The sacrificial layers 13 is, for example, a SiN film. The insulators 14 is, for example, a SiO₂ film. The sacrificial layers 13 is an example of a second insulator, and the insulators 14 is an example of a first insulator.

Subsequently, a plurality of memory holes MH, a plurality of contact holes CH, and a plurality of holes HR are formed in the stacked film 12 by photolithography and reactive ion etching (RIE) (FIG. 2). The memory holes MH, the contact holes CH, and the holes HR each have a column shape extending in the Z direction and have a circular shape in a plan view. The memory holes MH, the contact holes CH, and the holes HR may be simultaneously or sequentially formed. In FIG. 2, the memory holes MH, the contact holes CH, and the holes HR are formed at positions where these holes do not contact one another, and accordingly, are separated from one another.

Each memory hole MH is formed to penetrate through the stacked film 12 in a region R1 on the substrate 11. Each contact hole CH is formed to reach an upper face of the corresponding sacrificial layers 13 in a region R2 on the substrate 11. Each hole HR is formed to penetrate through the stacked film 12 in the region R2 on the substrate 11. The region R1 is used to dispose memory cells of the three-dimensional semiconductor memory, and the region R2 is used to dispose contact plugs for word lines and selection lines.

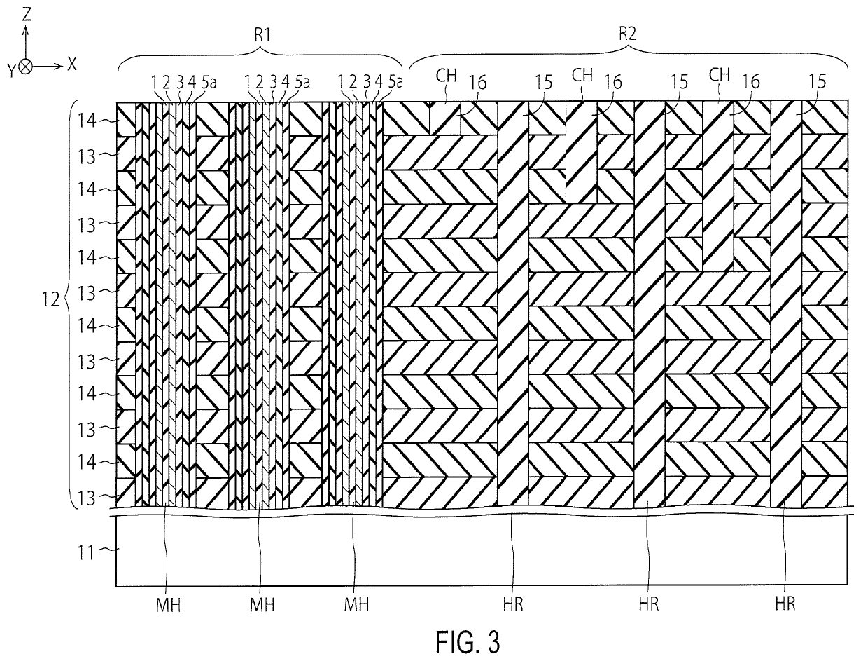

Subsequently, the insulator 5a, the charge storing layer 4, the tunnel insulator 3, the channel semiconductor layer 2, and the core insulator 1 are sequentially formed on a side face of the stacked film 12 in each memory hole MH (FIG. 3). As a result, a columnar portion including the core insulator 1, the channel semiconductor layer 2, the tunnel insulator 3, the charge storing layer 4, and the insulator 5a is formed in a column shape extending in the Z direction in each memory hole MH. The columnar portion is an example of the first columnar portion as described above.

Subsequently, an insulator 15 is formed in each hole HR, and a sacrificial layer 16 is formed in each contact hole CH (FIG. 3). As a result, a columnar portion including the insulator 15 is formed in a column shape extending in the Z direction in each hole HR, and a columnar portion including the sacrificial layer 16 is formed in a column shape extending in the Z direction in each contact hole CH. The former columnar portion is an example of a third columnar portion.

The insulator 15 is, for example, a SiO₂ film. The sacrificial layer 16 is, for example, a SiO₂ film. The insulator 15 and the sacrificial layer 16 are formed by, for example, embedding the same SiO₂ film in the hole HR and the contact hole CH.

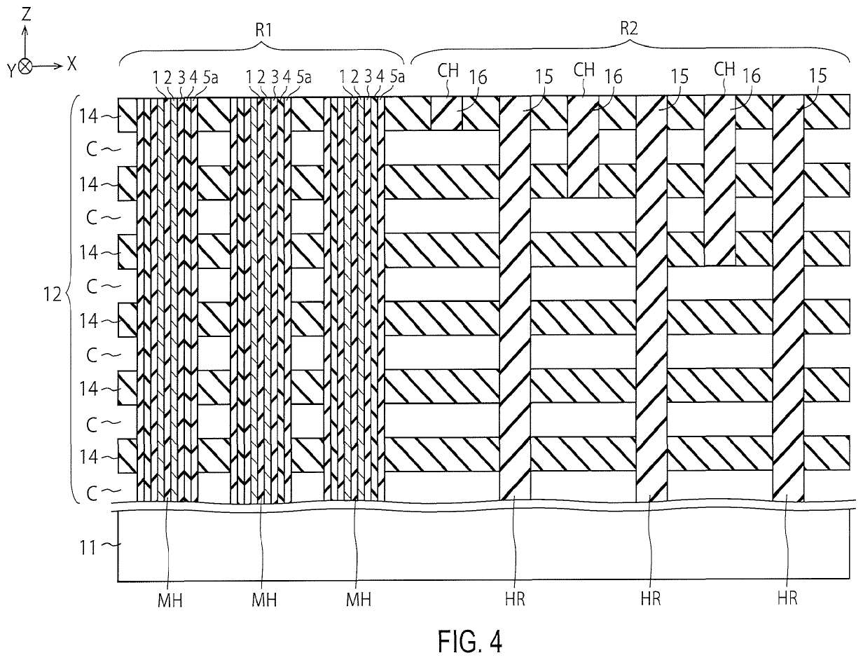

Subsequently, a plurality of slits (not illustrated) are formed in the stacked film 12, and the sacrificial layers 13 are removed from the slits by using liquid chemical such as phosphoric acid aqueous solution (FIG. 4). As a result, a plurality of concave portions C are formed in the stacked film 12.

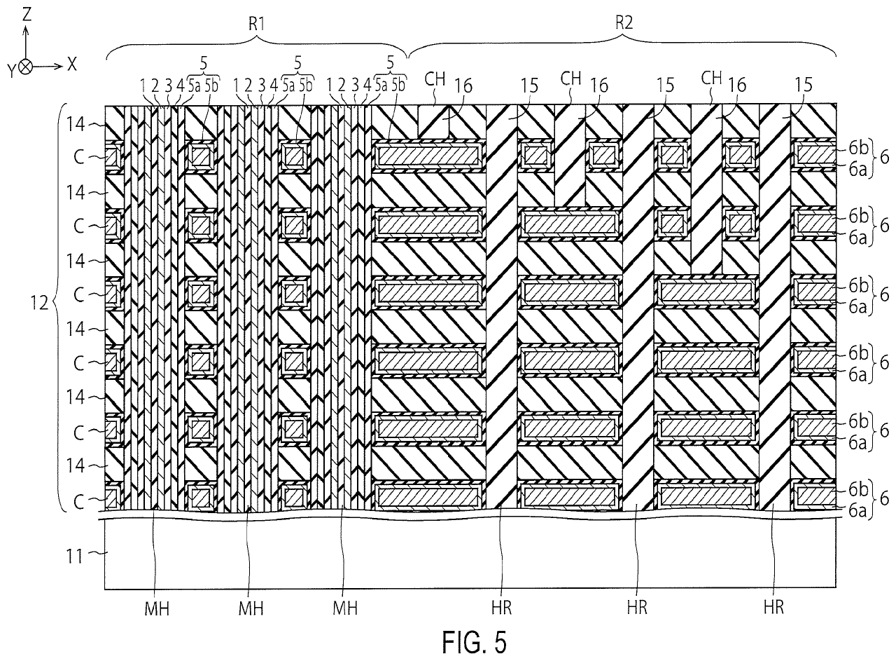

Subsequently, the insulator 5b, the barrier metal layer 6a, and the electrode material layer 6b are sequentially formed on surfaces of the insulators 5a and 14 in each concave portion C (FIG. 5). As a result, the block insulator 5 including the insulators 5a and 5b is formed. In addition, the electrode layer 6 including the barrier metal layer 6a and the electrode material layer 6b is formed in each concave portion C. Furthermore, the stacked film 12 alternately including the plurality of electrode layers 6 and the plurality of insulators 14 is formed on the 20 substrate 11. In this manner, a replacement process through which the sacrificial layers 13 are replaced with the electrode layers 6 is performed. The insulator 15 in each hole HR functions as a column (joist) for preventing collapse of the stacked film 12 in the replacement process.

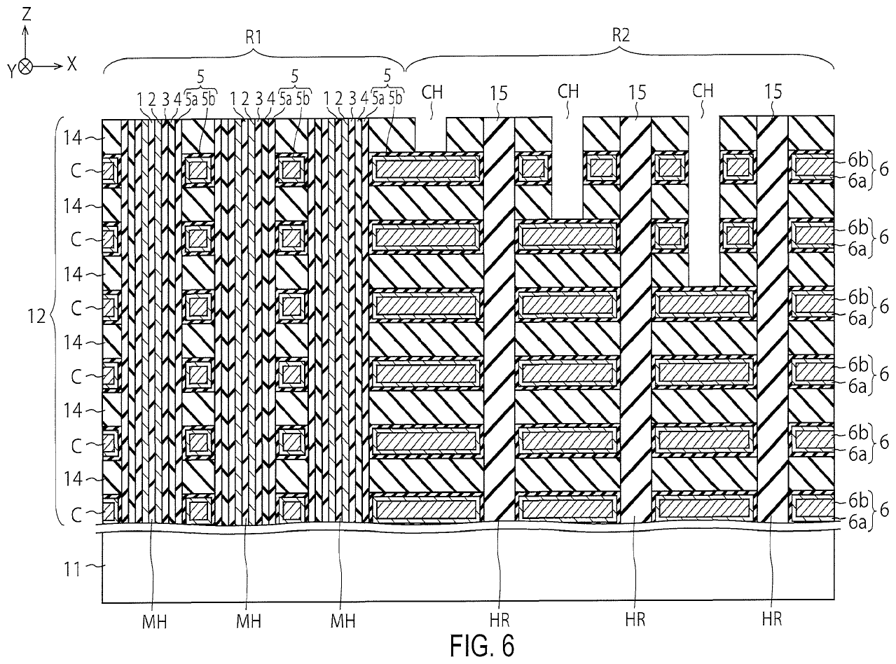

Subsequently, the sacrificial layers 16 are removed from the contact holes CH (FIG. 6). The sacrificial layers 16 are removed by, for example, wet process.

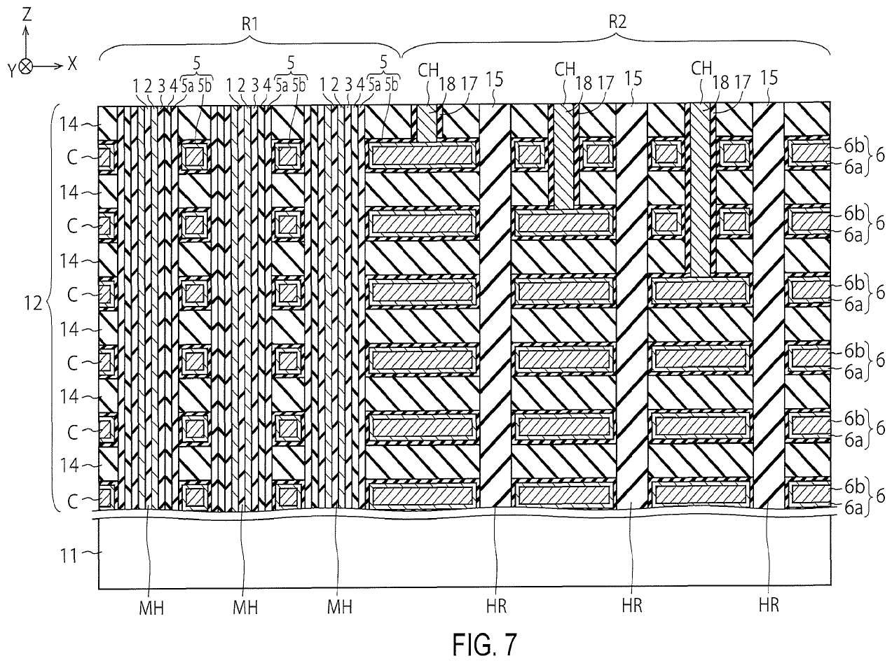

Subsequently, an insulator 17 is formed on side and bottom faces of each contact hole CH, the insulators 17 and 5b are removed from the bottom face of each contact hole CH, and a contact plug 18 is formed in each contact hole CH with the insulator 17 interposed therebetween (FIG. 7). As a result, each contact plug 18 is formed on the corresponding electrode layer 6. In addition, a columnar portion including the insulator 17 and the contact plug 18 is formed in a column shape extending in the Z direction in each contact hole CH. The columnar portion is an example of a second columnar portion. The insulator 17 is, for example, a SiO₂ film. The contact plug 18 is formed by using, for example, a metal layer such as a W (tungsten) layer.

In this manner, the semiconductor device of the present embodiment is manufactured (FIG. 7). FIG. 1 illustrates a portion of the semiconductor device illustrated in FIG. 7.

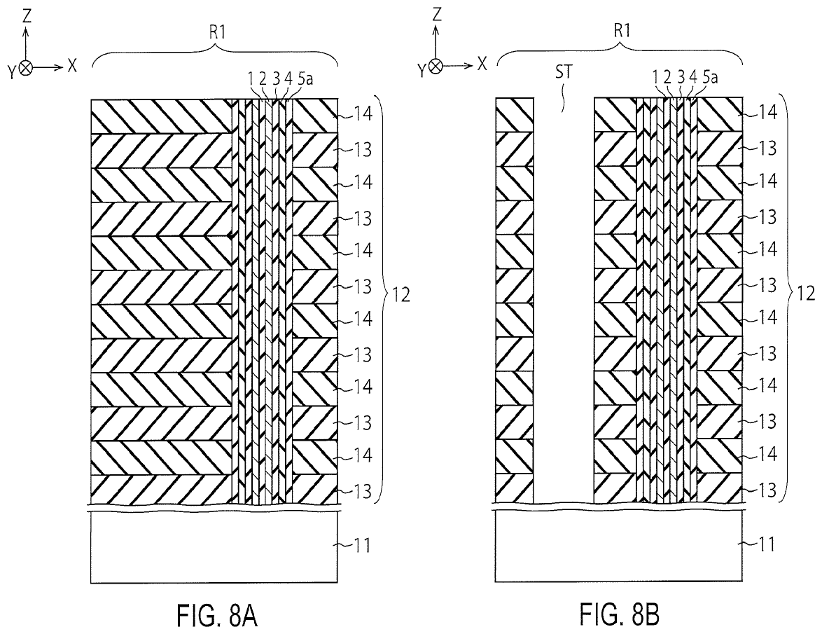

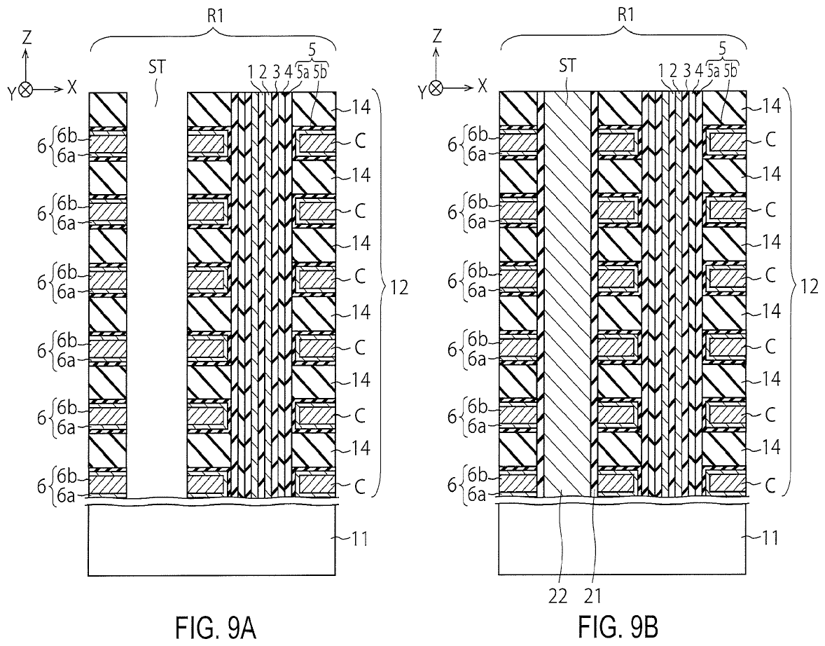

FIGS. 8 and 9 are cross-sectional views illustrating details of the method of manufacturing the semiconductor device of the first embodiment.

Processes illustrated in FIG. 8A to 9B are details of the processes illustrated in FIGS. 3 to 5. The cross-sectional view illustrated in FIG. 8A corresponds to the cross-sectional view illustrated in FIG. 3.

First, a plurality of slits ST are formed in the stacked film 12 by photolithography and RIE (FIG. 8B). FIG. 8B illustrates one of the slits ST. Each slit ST has a plate shape extending in the Z and Y directions and has a linear shape in a plan view. The slit ST illustrated in FIG. 8B is formed to penetrate through the stacked film 12 in the region R1 on the substrate 11.

Subsequently, the sacrificial layers 13 are removed from the slit ST by using liquid chemical, and a plurality of concave portions C are formed in the stacked film 12 (FIG. 9A). Subsequently, the insulator 5b, the barrier metal layer 6a, and the electrode material layer 6b are sequentially formed on surfaces of the concave portions C and the slit ST, and thereafter, excess of the insulator 5b, the barrier metal layer 6a, and the electrode material layer 6b in the slit ST is removed (FIG. 9A). As a result, the insulator 5b, the barrier metal layer 6a, and the electrode material layer 6b are sequentially formed on surfaces of the insulators 5a and 14 in each concave portion C. In this manner, a replacement process through which the sacrificial layers 13 are replaced with the electrode layers 6 is performed.

Subsequently, an insulator 21 and an interconnect layer 22 are sequentially formed in each slit ST (FIG. 9B). As a result, a plate portion including the insulator 21 and the interconnect layer 22 is formed in a plate shape extending in the Z and Y directions in each slit ST. The insulator 21 is, for example, a SiO₂ film. The interconnect layer 22 is, for example, a metal layer such as a W (tungsten) layer. The plate portion may be formed only by the insulator 21.

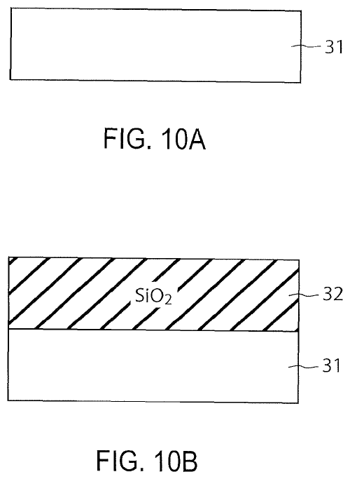

FIGS. 10A and 10B are cross-sectional views illustrating the method of manufacturing the semiconductor device of the first embodiment.

FIGS. 10A and 10B illustrate a method of forming a SiO₂ film formed when the semiconductor device of the present embodiment is manufactured. FIGS. 10A and 10B illustrates a process through which an underlaying film 31 is prepared (FIG. 10A) and a SiO₂ film 32 is formed on a surface of the underlaying film 31 (FIG. 10B). The underlaying film 31 is an example of a first film. The SiO₂ film 32 is an example of a second film including silicon and oxygen.

Examples of the SiO₂ film 32 include the core insulator 1, the tunnel insulator 3, the insulator 5a, the insulators 14, the insulator 15, the sacrificial layer 16, the insulator 17, and the insulator 21. For example, in a case where the SiO₂ film 32 is the insulator 15, the underlaying film 31 is the sacrificial layers 13, the insulators 14, and the like (refer to FIG. 3). In a case where the SiO₂ film 32 is the insulator 21, the underlaying film 31 is the electrode layers 6, the insulators 14, and the like (refer to FIG. 9B).

The SiO₂ film 32 of the present embodiment is formed by supplying aminosilane-based gas, other silane-based gas, and an oxidant to the surface of the underlaying film 31 as described later. Accordingly, the high-quality SiO₂ film 32 can be formed at low temperature. For example, the SiO₂ film 32 with a high density and a low contraction degree can be formed at low temperature. The aminosilane-based gas and the other silane-based gas are examples of the first silane-based gas and the second silane-based gas, respectively.

Such a SiO₂ film 32 is desirably used at, for example, a portion where high rigidity is required. For example, each above-described columnar portion having an elongated shape is desirably formed by using the SiO₂ film 32. This is true for each above-described plate portion as well. Accordingly, at least one of the core insulator 1, the tunnel insulator 3, the insulator 5a, the insulator 15, the insulator 17, and the insulator 21 is desirably the SiO₂ film 32.

However, in a case where a columnar portion includes the channel semiconductor layer 2, the rigidity of the columnar portion can be increased by using the channel semiconductor layer 2. Similarly, in a case where a columnar portion includes the contact plug 18, the rigidity of the columnar portion can be increased by using the contact plug 18. However, a columnar portion including the insulator 15 includes no other film than the insulator 15 in FIG. 3, for example. Accordingly, the insulator 15 is desirably the SiO₂ film 32. In this case, the rigidity of the columnar portion that functions as a joist can be increased.

Since the SiO₂ film 32 of the present embodiment is formed by using the aminosilane-based gas, the other silane-based gas, and the oxidant, the SiO₂ film 32 is formed to include nitrogen as impurity. The SiO₂ film 32 is formed to include nitrogen, for example, at a nitrogen concentration lower than 1.0×10²⁰ atoms/cm³. The nitrogen concentration in the SiO₂ film 32 is, for example, equal to or higher than 1.0×10¹⁸ atoms/cm³ and lower than 1.0×10²⁰ atoms/cm³.

To adjust the shape of each memory hole MH, the SiO₂ film 32 may be formed in the memory hole MH before formation of the insulator 5a. The SiO₂ film 32 in this case may be a portion of the insulator 5a.

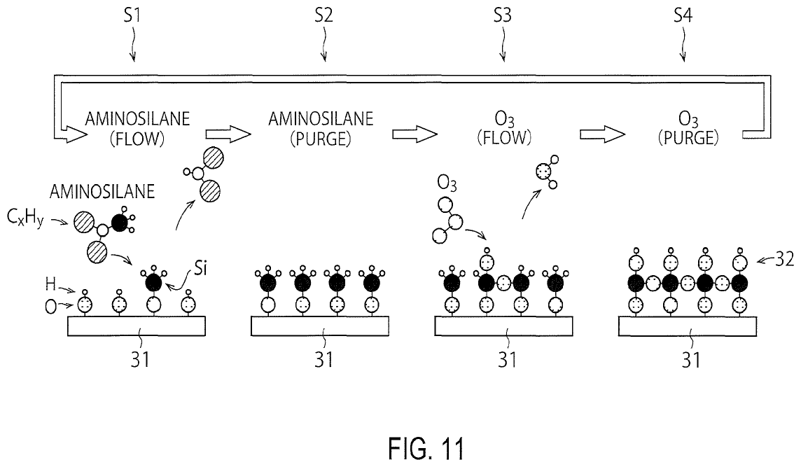

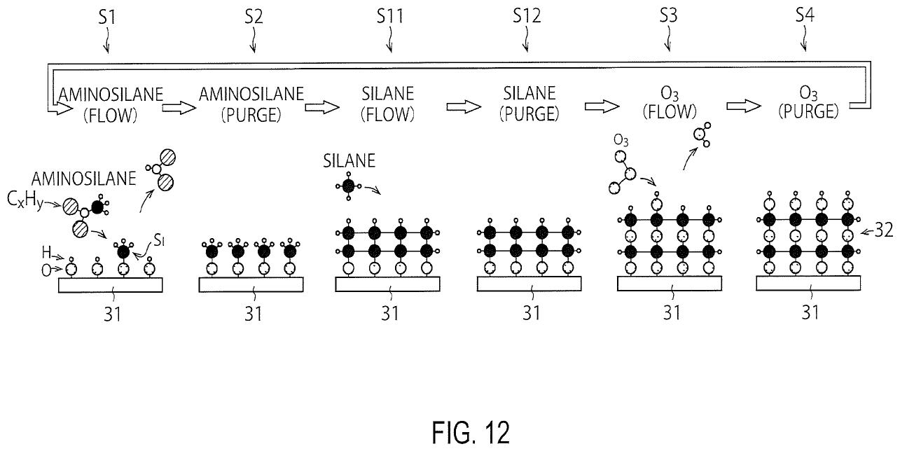

The first embodiment is compared to a comparative example with reference to FIGS. 11 and 12 below.

FIG. 11 is a schematic diagram illustrating a method of manufacturing a semiconductor device of the comparative example of the first embodiment. FIG. 11 illustrates the flow of a process through which the SiO₂ film 32 is formed on the surface of the underlaying film 31. The first silane-based gas and the second silane-based gas illustrated in FIG. 11 are examples and do not limit effects.

First, the substrate 11 (refer to FIG. 2) is housed in a chamber of an atomic layer deposition (ALD) device and aminosilane-based gas is supplied into the chamber (step S1). As a result, the aminosilane-based gas is supplied to the surface of the underlaying film 31. Before the method illustrated in FIG. 11 is started, the surface of the underlaying film 31 is a hydrophilic surface and OH groups (hydroxy groups) are present on the surface of the underlaying film 31. Each OH group reacts with an amino group in an aminosilane molecule, and as a result, silicon is adsorbed onto the surface of the underlaying film 31. In FIG. 11, a SiH₃ group (silyl group) separated from an aminosilane molecule bonds with an OH group, and as a result, the SiH₃ group is adsorbed onto the surface of the underlaying film 31. Subsequently, the aminosilane-based gas is purged from the chamber (step S2).

Subsequently, an oxidant is supplied into the chamber (step S3). As a result, the oxidant is supplied to the surface of the underlaying film 31. The oxidant oxidizes the silicon adsorbed onto the surface of the underlaying film 31, and as a result, oxygen atoms in molecules included in the oxidant bond with silicon atoms adsorbed onto the surface of the underlaying film 31. In FIG. 11, O₃ (ozone) gas included in the oxidant oxidizes a SiH₃ group adsorbed onto the surface of the underlaying film 31, and as a result, an oxygen atom separated from an O₃ molecule bonds with a silicon atom attributable to the SiH₃ group and is adsorbed onto the surface of the underlaying film 31. In FIG. 11, due to an effect of the oxidant, OH groups are formed on the surface of the underlaying film 31 again. Subsequently, the oxidant is purged from the chamber (step S4). In this manner, the SiO₂ film 32 is formed on the surface of the underlaying film 31 by ALD.

Thereafter, the processing including steps S1, S2, S3, and S4 is repeated a plurality of cycles in the order of S1, S2, S3, and S4 as illustrated in FIG. 11. In this manner, the SiO₂ film 32 having a desired film thickness can be formed on the surface of the underlaying film 31.

In the present comparative example, to increase the density of the SiO₂ film 32 and lower the contraction degree of the SiO₂ film 32, a large number of Si—Si bonds need to be formed in the SiO₂ film 32 at steps S1 to S4. To form a large number of Si—Si bonds in the SiO₂ film 32, the SiO₂ film 32 need to be formed at high temperature, and the SiO₂ film 32 is desirably formed, for example, at a temperature higher than the thermal decomposition temperature (self-decomposition temperature) of aminosilane. However, formation of the SiO₂ film 32 at high temperature has constraints in terms of temperature and time from a viewpoint of thermal budget in some cases. Furthermore, film thickness uniformity and coverage of the SiO₂ film 32 potentially degrade in a case where the SiO₂ film 32 is formed at high temperature.

FIG. 12 is a schematic diagram illustrating the method of manufacturing the semiconductor device of the first embodiment. FIG. 12 illustrates the flow of another process through which the SiO₂ film 32 is formed on the surface of the underlaying film 31.

First, the substrate 11 (refer to FIG. 2) is housed in a chamber of an ALD device and aminosilane-based gas is supplied into the chamber (step S1). As a result, the aminosilane-based gas is supplied to the surface of the underlaying film 31. Before the method illustrated in FIG. 12 is started, the surface of the underlaying film 31 is a hydrophilic surface and OH groups are present on the surface of the underlaying film 31. Each OH group bonds with a silicon atom in an aminosilane molecule, and as a result, silicon is adsorbed onto the surface of the underlaying film 31. In FIG. 12, a SiH₃ group separated from an aminosilane molecule bonds with an OH group, and as a result, the SiH₃ group is adsorbed onto the surface of the underlaying film 31. Subsequently, the aminosilane-based gas is purged from the chamber (step S2).

The aminosilane-based gas used at step S1 includes, for example, BDEAS (bis(diethylamino) silane), TrisDMAS (Tris(dimethylamino) silane), DIPAS (di(isopropylamino) silane), or BTBAS (Bis(tert-butylamino) silane). The aminosilane-based gas listed above is an example and may be other aminosilane-based gas. The aminosilane-based gas used at step S1 is an example of the first silane-based gas.

Subsequently, silane-based gas is supplied into the chamber (step S11). As a result, the silane-based gas is supplied to the surface of the underlaying film 31. The silane-based gas is different from the aminosilane-based gas used at step S1 and has a thermal decomposition temperature lower than the thermal decomposition temperature of the aminosilane-based gas. The silane-based gas used at step S11 is, for example, silane-based gas (non-aminosilane-based gas) that is not aminosilane-based gas, and/or inorganic silane-based gas including no carbon. At step S11, a silicon atom in a silane molecule bonds with a silicon atom adsorbed onto the surface of the underlaying film 31, and as a result, a silicon atom separated from the silane molecule is adsorbed onto the surface of the underlaying film 31. In FIG. 12, not only Si—O bonds but also Si—Si bonds are formed on the surface of the underlaying film 31. Subsequently, the silane-based gas is purged from the chamber (step S12).

The silane-based gas used at step S11 includes, for example, SiH₄ (monosilane), Si₂H₆ (disilane), DCS (dichlorosilane), TCS (trichlorosilane), or HCD (hexachlorodisilane). The silane-based gas listed above is an example and may be other silane-based gas. The silane-based gas used at step S11 is an example of the second silane-based gas.

Subsequently, an oxidant is supplied into the chamber (step S3). As a result, the oxidant is supplied to the surface of the underlaying film 31. The oxidant oxidizes silicon adsorbed onto the surface of the underlaying film 31, and as a result, an oxygen atom in a molecule included in the oxidant bonds with a silicon atom adsorbed onto the surface of the underlaying film 31. In FIG. 12, O₃ gas) included in the oxidant oxidizes the silicon adsorbed onto the surface of the underlaying film 31, and as a result, an oxygen atom separated from an O₃ molecule bonds with a silicon atom attributable to step S1 or S11 and is adsorbed onto the surface of the underlaying film 31. In FIG. 12, due to an effect of the oxidant, OH groups are formed on the surface of the underlaying film 31 again. Subsequently, the oxidant is purged from the chamber (step S4). In this manner, the SiO₂ film 32 is formed on the surface of the underlaying film 31 by ALD.

The oxidant used at step S3 includes, for example, O₃ gas, H₂O gas, or O₂ gas (O represents oxygen and H represents hydrogen). The oxidant used at step S3 may be other gas including oxygen.

Thereafter, the processing including steps S1, S2, S11, S12, S3, and S4 is repeated a plurality of cycles in the order of S1, S2, S11, S12, S3, and S4 as illustrated in FIG. 12. In this manner, the SiO₂ film 32 having a desired film thickness can be formed on the surface of the underlaying film 31. Steps S1, S11, and S3 are examples of first processing, second processing, and third processing, respectively. The processing at steps S1, S11, and S3 is performed at, for example, 300 to 600° C. in each cycle.

Further details of the method of manufacturing the semiconductor device of the present embodiment will be described below with reference to FIG. 12.

Before step S1 is started, OH groups are present on the surface of the underlaying film 31. Typically, aminosilane-based gas is likely to react with OH groups. For this reason, at step S1, aminosilane-based gas is supplied to the surface of the underlaying film 31 so that silicon can be easily adsorbed onto the surface of the underlaying film 31. Before step S11 is started, the surface of the underlaying film 31 is hydrophobized by silicon atoms attributable to step S1. In this case, even non-aminosilane-based gas is likely to react with silicon on the surface of the underlaying film 31. For this reason, at step S11, non-aminosilane-based gas is supplied to the surface of the underlaying film 31 so that Si—Si bonds can be formed on the surface of the underlaying film 31, and accordingly, silicon can be adsorbed onto the surface of the underlaying film 31.

According to the present embodiment, since a larger number of Si—Si bonds are formed at step S11, it is possible to increase the density of the SiO₂ film 32 and lower the contraction degree of the SiO₂ film 32 even when the SiO₂ film 32 is formed at low temperature. Moreover, according to the present embodiment, since the silane-based gas supplied at step S11 is inexpensive as compared to the aminosilane-based gas used at step S1, it is possible to reduce the total cost of gas used to form the SiO₂ film 32. Since non-aminosilane-based gas is typically inexpensive as compared to aminosilane-based gas, non-aminosilane-based gas is desirably used at step S11 from this viewpoint. In a case where carbon atoms potentially adversely affect the SiO₂ film 32, inorganic silane-based gas is desirably used at step S11.

The above-described Si—Si bonds are likely to be formed when the processing at step S11 is performed at a temperature higher than the thermal decomposition temperature of the silane-based gas used at step S11. For this reason, the thermal decomposition temperature of the silane-based gas used at step S11 is desirably low to form the SiO₂ film 32 at low temperature. Accordingly, in the present embodiment, the thermal decomposition temperature of the silane-based gas used at step S11 is lower than the thermal decomposition temperature of the aminosilane-based gas used at step S1. As a result, in formation of Si—Si bonds by using the silane-based gas at step S11, a large number of Si—Si bonds can be easily formed at low temperature as compared to formation of Si—Si bonds by using the aminosilane-based gas. In the present embodiment, the processing at steps S1, S11, and S3 is performed at, for example, 300 to 600° C.

As described above, the SiO₂ film 32 of the present embodiment is formed by using aminosilane-based gas, other silane-based gas, an oxidant. As a result, according to the present embodiment, the high-quality SiO₂ film 32 can be formed at low temperature. For example, according to the present embodiment, the SiO₂ film 32 with a high density and a low contraction degree can be formed at low temperature.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
supplying first silane-based gas to a surface of a first film, the first silane-based gas being aminosilane-based gas;
supplying second silane-based gas to the surface of the first film, the second silane-based gas having a thermal decomposition temperature lower than a thermal decomposition temperature of the first silane-based gas; and
supplying an oxidant to the surface of the first film to form a second film on the surface of the first film, the second film including silicon and oxygen.

2. The method of claim 1, wherein the surface of the first film is a hydrophilic surface before the first silane-based gas, the second silane-based gas, and the oxidant are supplied to the surface of the first film.

3. The method of claim 1, wherein the second film is a silicon oxide film including nitrogen as impurity.

4. The method of claim 1, wherein the second film is formed to include nitrogen at a nitrogen concentration less than 1.0×10²⁰ atoms/cm³.

5. The method of claim 1, wherein the first silane-based gas causes silicon adsorption onto the surface of the first film.

6. The method of claim 1, wherein the first silane-based gas includes BDEAS (bis(diethylamino) silane), TrisDMAS (Tris(dimethylamino) silane), DIPAS (di(isopropylamino) silane), or BTBAS (Bis(tert-butylamino) silane).

7. The method of claim 1, wherein the second silane-based gas causes silicon adsorption onto the surface of the first film.

8. The method of claim 1, wherein the second silane-based gas is non-aminosilane-based gas.

9. The method of claim 1, wherein the second silane-based gas is inorganic silane-based gas.

10. The method of claim 1, wherein the second silane-based gas includes SiH₄ (monosilane), Si₂H₆ (disilane), DCS (dichlorosilane), TCS (trichlorosilane), or HCD (hexachlorodisilane).

11. The method of claim 1, wherein the oxidant oxidizes silicon adsorbed onto the surface of the first film.

12. The method of claim 1, wherein the oxidant includes O₃, H₂O or O₂, where O represents oxygen and H represents hydrogen.

13. The method of claim 1, wherein the first silane-based gas, the second silane-based gas, and the oxidant are supplied at 300 to 600° C.

14. The method of claim 1, wherein the second film is formed on the surface of the first film by alternately repeating first processing of supplying the first silane-based gas, second processing of supplying the second silane-based gas, and third processing of supplying the oxidant.

15. The method of claim 1, further comprising:
forming a stacked film including a plurality of first insulators and a plurality of second insulators that are alternately stacked in a first direction; and
replacing the plurality of second insulators with a plurality of electrode layers,
wherein the second film is formed in the stacked film.

16. The method of claim 15, further comprising:
forming a first columnar portion in the stacked film, the first columnar portion including a charge storing layer and a semiconductor layer, and having a column shape extending in the first direction;
forming a second columnar portion in the stacked film, the second columnar portion having a column shape extending in the first direction, including a contact plug, and being separated from the first columnar portion; and
forming a third columnar portion in the stacked film, the third columnar portion having a column shape extending in the first direction, and being separated from the first columnar portion and the second columnar portion,
wherein the second film is formed in the first columnar portion, the second columnar portion, or the third columnar portion.

17. The method of claim 15, further comprising forming a plate portion in the stacked film, the plate portion having a plate shape extending in the first direction and a second direction,
wherein the second film is formed in the plate portion.

18. A semiconductor device comprising:
a first film;
a second film as a silicon oxide film that is provided on a surface of the first film, and includes nitrogen at a nitrogen concentration equal to or higher than 1.0×10¹⁸ atoms/cm³ and lower than 1.0×10²⁰ atoms/cm³ as impurity; and
a stacked film including a plurality of first insulators and a plurality of electrode layers that are alternately stacked in a first direction, wherein the second film is provided in the stacked film.

19. The device of claim 18, further comprising:
a first columnar portion provided in the stacked film, including a charge storing layer and a semiconductor layer, and having a column shape extending in the first direction;
a second columnar portion provided in the stacked film, having a column shape extending in the first direction, including a contact plug, and separated from the first columnar portion; and
a third columnar portion provided in the stacked film, having a column shape extending in the first direction, and separated from the first columnar portion and the second columnar portion,
wherein the second film is provided in the first columnar portion, the second columnar portion, or the third columnar portion.

20. The device of claim 18, further comprising a plate portion provided in the stacked film, and having a plate shape extending in the first direction and a second direction,
wherein the second film is provided in the plate portion.
